(19) United States
(12) Patent Application Publication
(10) Pub. No.: US 2008/0072929 A1
(43) Pub. Date: Mar. 27, 2008

(54) DILUTION GAS RECIRCULATION

(76) Inventor: JOHN M. WHITE, Hayward, CA (US)

Correspondence Address: PATTERSON & SHERIDAN, LLP, 3040 POST OAK BOULEVARD, SUITE 1500, HOUSTON, TX, 77056, US

(21) Appl. No.: 11/565,400

(22) Filed: Nov. 30, 2006

Related U.S. Application Data
(60) Provisional application No. 60/826,718, filed on Sep. 22, 2006.

(51) Int. Cl. C23C 16/00; H01L 21/306

(52) U.S. Cl. 134/11; 118/723 R

(57) ABSTRACT

The present invention comprises a method and an apparatus for recirculating a process gas through a system. The process gas may be evacuated from the chamber, and a portion of the process gas may pass through at least a particle trap/filter while another portion of the process gas may be evacuated through mechanical backing pumps. The process gas that passes through the particle trap/filter may then join fresh, unrecirculated process gas and enter the processing chamber. The recirculated gas may join the fresh, unrecirculated processing gas after the fresh, unrecirculated processing gas has passed through a remote plasma source. The plasma generated in the remote plasma source may ensure that the recirculated process gas does not deposit on the conduits leading into the process chamber. The amount of gas recirculated may determine the amount of fresh, unrecirculated process gas that may be delivered to the process chamber.

### CROSS-REFERENCE TO RELATED APPLICATIONS

This application claims benefit of U.S. provisional patent application Ser. No. 60/826,718, filed Sep. 22, 2006, which is herein incorporated by reference.

### BACKGROUND OF THE INVENTION

1. Field of the Invention

Embodiments of the present invention generally relate to a method and apparatus for recirculating process gases in a plasma enhanced chemical vapor deposition (PECVD) process.

2. Description of the Related Art

PECVD is a method for depositing a material onto a substrate by igniting process gases into a plasma state. Process gases may be continually provided to the chamber until a desired thickness of the material deposited is achieved. During processing, the process gases may be exhausted from the process chamber in order to maintain a constant pressure within the chamber. Therefore, there is a need in the art to provide process gases to a PECVD chamber and exhaust gases from a PECVD chamber in an efficient, cost effective manner.

### SUMMARY OF THE INVENTION

The present invention comprises a method and an apparatus for recirculating a process gas through a system. The process gas may be evacuated from the chamber, and a portion of the process gas may pass through at least a particle trap/filter while another portion of the process gas may be evacuated through mechanical backing pumps. The process gas that passes through the particle trap/filter may then join fresh, unrecirculated process gas and enter the processing chamber. The recirculated gas may join the fresh, unrecirculated processing gas after the fresh, unrecirculated processing gas has passed through a remote plasma source. The plasma generated in the remote plasma source may ensure that the recirculated process gas does not deposit on the conduits leading into the process chamber. The amount of gas recirculated may determine the amount of fresh, unrecirculated process gas that may be delivered to the process chamber.

In one embodiment, a plasma enhanced chemical vapor deposition method is disclosed. The method comprises providing a fresh, unrecirculated processing gas to a plasma enhanced chemical vapor deposition chamber, performing a plasma enhanced chemical vapor deposition process, exhausting the processing gas from the chamber, and recirculating at least a portion of the processing gas through gas reconditioning hardware that includes at least one item selected from the group consisting of a particle trap, a particle filter, and combinations thereof. The processing gas comprises a diluting gas and a deposition gas.

In another embodiment, another plasma enhanced chemical vapor deposition method is disclosed. The method comprises providing a fresh, unrecirculated processing gas to a plasma enhanced chemical vapor deposition chamber, performing a plasma enhanced chemical vapor deposition process, exhausting the processing gas from the chamber, and recirculating at least a portion of the processing gas through gas reconditioning hardware that includes at least one item selected from the group consisting of a particle trap, a particle filter, and combinations thereof. The processing gas comprises at least hydrogen and a silane.

In still another embodiment, a plasma enhanced chemical vapor deposition apparatus is disclosed. The apparatus comprises a chamber, a processing gas source coupled with the chamber, a first pressure gauge coupled between the processing gas source and the chamber, and a chamber exhaust system coupled with the chamber. The exhaust system comprises at least one exhaust conduit coupled with the chamber, a particle filter coupled along the at least one exhaust conduit, a particle filter exhaust conduit coupled with the particle filter and the chamber; and at least one throttle valve coupled with the particle filter exhaust conduit and electrically coupled with the first pressure gauge.

In still another embodiment, a plasma enhanced chemical vapor deposition apparatus is disclosed. The apparatus comprises a chamber, a processing gas source coupled with the chamber, a first pressure gauge coupled between the processing gas source and the chamber, and a chamber exhaust system coupled with the chamber. The exhaust system comprises at least one exhaust conduit coupled with the chamber, at least one throttle valve electrically coupled with the first pressure gauge along the at least one exhaust conduit, a particle filter coupled between the chamber and the at least one throttle valve along the at least one exhaust conduit, and a particle filter exhaust conduit coupled with the particle filter and the chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a sectional view of a PECVD chamber 100 that may be used in connection with one or more embodiments of the invention.

FIG. 2 is a drawing showing one embodiment of a dilution gas recirculation system 200.

FIG. 3 is a drawing showing another embodiment of a dilution gas recirculation system 300.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention comprises a method and an apparatus for recirculating a process gas through a system. The process gas may be evacuated from the chamber, and a portion of the process gas may pass through at least a particle trap/filter while another portion of the process gas may be evacuated through mechanical backing pumps. The process gas that passes through the particle trap/filter may then join fresh, unrecirculated process gas and enter the processing chamber. The recirculated gas may join the fresh, unrecirculated processing gas after the fresh, unrecirculated processing gas has passed through a remote plasma source. The plasma generated in the remote plasma source may ensure that the recirculated process gas does not deposit on the conduits leading into the process chamber. The amount of gas recirculated may determine the amount of fresh, unrecirculated process gas that may be delivered to the process chamber.

### PECVD System

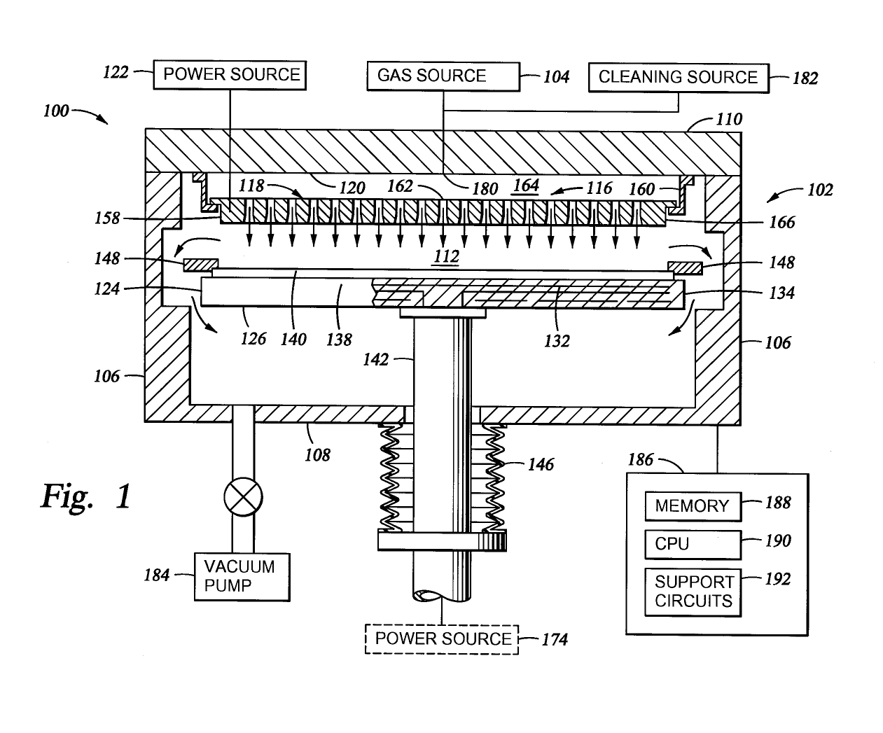

FIG. 1 is a schematic cross-sectional view of one embodiment of a PECVD system 100, available from AKT®, a division of Applied Materials, Inc., Santa Clara, Calif. The system 100 may include a processing chamber 102 coupled to a gas source 104. The processing chamber 102 has walls 106 and a bottom 108 that partially define a process volume 112. The process volume 112 may be accessed through a port (not shown) in the walls 106 that facilitate movement of a substrate 140 into and out of the processing chamber 102. The walls 106 and bottom 108 may be fabricated from a unitary block of aluminum or other material compatible with processing. The walls 106 support a lid assembly 110. The processing chamber 102 may be evacuated by a vacuum pump 184.

A temperature controlled substrate support assembly 138 may be centrally disposed within the processing chamber 102. The support assembly 138 may support a substrate 140 during processing. In one embodiment, the substrate support assembly 138 comprises an aluminum body 124 that encapsulates at least one embedded heater 132. The heater 132, such as a resistive element, disposed in the support assembly 138, may be coupled to a power source 174 and controllably heats the support assembly 138 and the substrate 140 positioned thereon to a predetermined temperature. The heater 132 may maintain the substrate 140 at a uniform temperature between about 150 degrees Celsius to at least about 460 degrees Celsius, depending on the deposition processing parameters for the material being deposited.

The substrate support assembly 138 may include a two zone embedded heater. One zone may be an inner heating zone that is located near the center of the substrate support assembly 138. The outer heating zone may be located near the outer edge of the substrate support assembly 138. The outer heating zone may be set to a higher temperature do to higher thermal losses that may occur at the edge of the substrate support assembly 138. An exemplary two zone heating assembly that may be used to practice the present invention is disclosed in U.S. Pat. No. 5,844,205, which is hereby incorporated by reference in its entirety.

The support assembly 138 may have a lower side 126 and an upper side 134. The upper side 134 supports the substrate 140. The lower side 126 may have a stem 142 coupled thereto. The stem 142 couples the support assembly 138 to a lift system (not shown) that moves the support assembly 138 between an elevated processing position (as shown) and a lowered position that facilitates substrate transfer to and from the processing chamber 102. The stem 142 additionally provides a conduit for electrical and thermocouple leads between the support assembly 138 and other components of the system 100.

A bellows 146 may be coupled between support assembly 138 (or the stem 142) and the bottom 108 of the processing chamber 102. The bellows 146 provides a vacuum seal between the chamber volume 112 and the atmosphere outside the processing chamber 102 while facilitating vertical movement of the support assembly 138.

The support assembly 138 may be grounded such that RF power supplied by a power source 122 to a gas distribution plate assembly 118 positioned between the lid assembly 110 and substrate support assembly 138 (or other electrode positioned within or near the lid assembly of the chamber) may excite gases present in the process volume 112 between the support assembly 138 and the distribution plate assembly 118. The RF power from the power source 122 may be selected commensurate with the size of the substrate to drive the chemical vapor deposition process.

The support assembly 138 may additionally support a circumscribing shadow frame 148. The shadow frame 148 may prevent deposition at the edge of the substrate 140 and support assembly 138 so that the substrate may not stick to the support assembly 138.

The lid assembly 110 provides an upper boundary to the process volume 112. The lid assembly 110 may be removed or opened to service the processing chamber 102. In one embodiment, the lid assembly 110 may be fabricated from aluminum.

The lid assembly 110 may include an entry port 180 through which process gases provided by the gas source 104 may be introduced into the processing chamber 102. The entry port 180 may also be coupled to a cleaning source 182. The cleaning source 182 may provide a cleaning agent, such as disassociated fluorine, that may be introduced into the processing chamber 102 to remove deposition by-products and films from processing chamber hardware, including the gas distribution plate assembly 118.

The gas distribution plate assembly 118 may be coupled to an interior side 120 of the lid assembly 110. The gas distribution plate assembly 118 may be configured to substantially follow the profile of the substrate 140, for example, polygonal for large area flat panel substrates and circular for substrates. The gas distribution plate assembly 118 may include a perforated area 116 through which process and other gases supplied from the gas source 104 may be delivered to the process volume 112. The perforated area 116 of the gas distribution plate assembly 118 may be configured to provide uniform distribution of gases passing through the gas distribution plate assembly 118 into the processing chamber 102. Gas distribution plates that may be adapted to benefit from the invention are described in commonly assigned U.S. Pat. Nos. 6,477,980; 6,772,827; 7,008,484; 6,942,753 and U.S. patent Published application Nos. 2004/0129211 A1, which are hereby incorporated by reference in their entireties.

The gas distribution plate assembly 118 may include a diffuser plate 158 suspended from a hanger plate 160. The diffuser plate 158 and hanger plate 160 may alternatively comprise a single unitary member. A plurality of gas passages 162 may be formed through the diffuser plate 158 to allow a predetermined distribution of gas passing through the gas distribution plate assembly 118 and into the process volume 112. The hanger plate 160 maintains the diffuser plate 158 and the interior surface 120 of the lid assembly 110 in a spaced-apart relation, thus defining a plenum 164 therebetween. The plenum 164 may allow gases flowing through the lid assembly 110 to uniformly distribute across the width of the diffuser plate 158 so that gas may be provided uniformly above the center perforated area 116 and flow with a uniform distribution through the gas passages 162.

The diffuser plate 158 may be fabricated from stainless steel, aluminum, anodized aluminum, nickel or any other RF conductive material. The diffuser plate 158 may be configured with a thickness that maintains sufficient flatness across the aperture 166 as not to adversely affect substrate processing. In one embodiment the diffuser plate 158 may have a thickness between about 1.0 inch to about 2.0 inches. The diffuser plate 158 may be circular for semiconductor substrate manufacturing or polygonal, such as rectangular, for flat panel display manufacturing.

As shown in FIG. 1, a controller 186 may interface with and control various components of the substrate processing system. The controller 186 may include a central processing unit (CPU) 190, support circuits 192 and a memory 188.

The processing gas may enter into the chamber 102 from the gas source 104 and be exhausted out of the chamber 102 by a vacuum pump 184. As will be discussed below, fresh, unrecirculated process gas may be provided from the gas source 104 to the chamber 102 through a remote plasma source (not shown). Portions of the gas evacuated from the chamber 102 may pass through at least a particle trap/filter and then be recirculated back to the chamber 102. The recirculated processing gas may connect back to the chamber 102 at a location after the remote plasma source. Exemplary gases that may be recirculated include H₂, silanes, PH₃, or TMB.

### Recirculation System

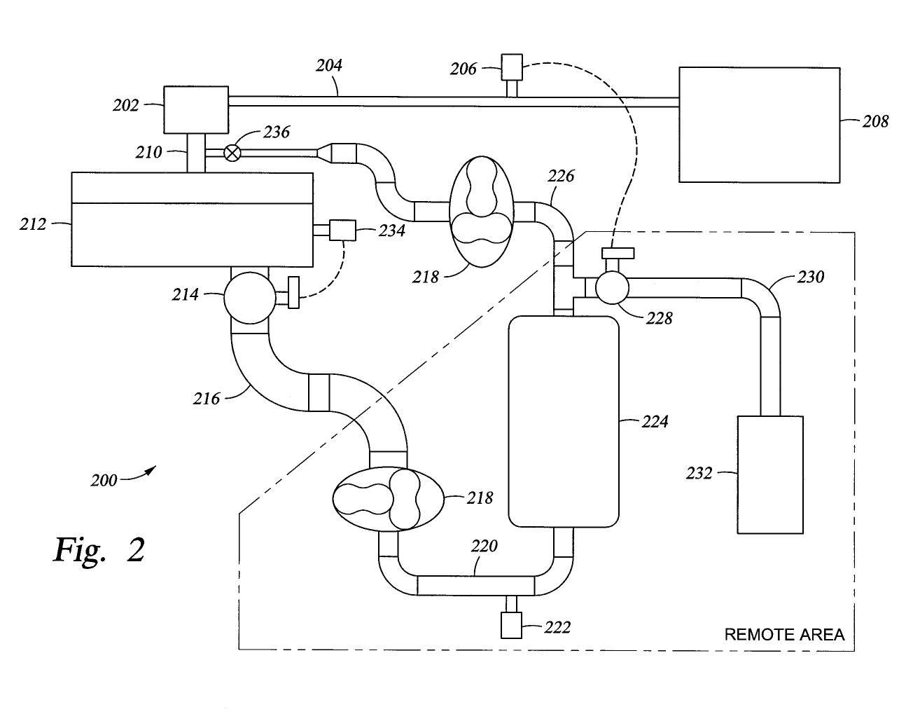

FIG. 2 is a drawing showing one embodiment of a dilution gas recirculation system 200. As may be seen from FIG. 2, a process gas may initially be provided to a processing chamber 212 from a gas panel 208 through inlet conduits 204, 210. A remote plasma source 202 may be positioned along the inlet conduits 204, 210 to strike a plasma remotely from the process chamber 212. By striking a plasma remotely from the chamber 212, the plasma generated in the remote plasma source 202 may pass through the inlet conduit 210 and keep the inlet conduit 210 free of deposits.

The process chamber 212 may be evacuated to remove the processing gases. One or more mechanical backing pumps 232 may be positioned to evacuate the processing chamber 212. One or more pressure boosting devices 218 may additionally be provided between the processing chamber 212 and the one or more mechanical backing pumps 232 to aid in evacuating the chamber 212. In one embodiment, the pressure boosting device 218 may be a roots blower. In another embodiment, the pressure boosting device 218 may be a mechanical pump. Additionally, a pressure boosting device 218 may be positioned along the conduit 226 back to the processing chamber 212. A chamber pressure gauge 234 may be coupled with the processing chamber 212 to measure the pressure within the processing chamber 212. A chamber throttle valve 214 may be positioned along the exit conduit 216. The chamber throttle valve 214 may be coupled with the chamber pressure gauge 234. Based upon the pressure as measured at the chamber pressure gauge 234, the amount that the chamber throttle valve 214 is opened may be adjusted. By coupling the chamber throttle valve 214 and the chamber pressure gauge 234 together, a predetermined chamber pressure may be maintained. In one embodiment, the chamber pressure may be about 0.3 Torr to about 25 Torr. In another embodiment, the chamber pressure may be about 0.3 Torr to about 15 Torr.

A portion of the evacuated processing gas may be recirculated to the processing chamber 212. The evacuated processing gas passes through the chamber throttle valve 214 and the roots blower 218 along conduits 216, 220 to at least a particle trap/filter 224. The pressure of the process gas within the conduit 220 may be measured with an exhaust pressure gauge 222 positioned along the conduit 220. The particle trap/filter 224 may reduce the amount of particles present within the processing gas. By reducing the amount of particles present within the processing gas, the amount of deposition that may occur in conduits 226, 210 leading to the processing chamber 212 may be reduced. In one embodiment, the particle trap/filter 224 may be made of stainless steel.

The particle trap/filter 224 and the recirculation system may be cleaned periodically to ensure that any clogging that may occur in the recirculation system or the particle trap/filter 224 may be reduced. The particle trap/filter 224 may be made of a material compatible with etching gases such as NF₃ or F₂ among others to ensure that the particle trap/filter 224 does not need replacing. In one embodiment, a water flush may be used to clean the recirculation system and particle trap/filter 224. In another embodiment, etching gas such as NF₃ or F₂ may be used to clean the recirculation system and particle trap/filter 224.

The amount of processing gas that is recirculated may be controlled by a recirculation throttle valve 228. The amount that the recirculation throttle valve 228 is opened determines the amount of processing gas that may be recirculated and the amount of processing gas that may be evacuated to the mechanical backing pumps 232 through the conduit 230. The more that the recirculation throttle valve 228 is opened, the more processing gases that are evacuated to the mechanical backing pumps 232. The less that the recirculation throttle valve 228 is opened, the more processing gas is recirculated back to the processing chamber 212. A shut-off valve 236 may be positioned where the recirculation conduit 226 joins the conduit 210 leading to the processing chamber 210 so that, as desired, the recirculation may be prevented.

The recirculation throttle valve 228 may be coupled with the inlet pressure gauge 206. By coupling the inlet pressure gauge 206 to the recirculation throttle valve 228, the amount that the recirculation throttle valve 228 is opened may be controlled based upon the pressure as measured at the inlet pressure gauge 206. Hence, the amount of gas recirculated is a function of the pressure as measured at the inlet pressure gauge 206. In one embodiment, the pressure as measured at the inlet pressure gauge 206 may be about 1 Torr to about 100 Torr. In another embodiment, the pressure as measured at the inlet pressure gauge 206 may be about 1 Torr to about 20 Torr. A desired mass flow rate of processing gas to the processing chamber 212 may be controlled. Once a desired mass flow rate to the processing chamber 212 is determined, the mass flow rate of fresh, unrecirculated processing gas may be set and the amount of processing gas recirculated may be adjusted as a function of the fresh, unrecirculated processing gas so that the combined flow of the fresh, unrecirculated processing gas and the recirculated processing gas equals the desired mass flow rate to the chamber 212.

The recirculated processing gas may join with the fresh, unrecirculated processing gas at a location between the remote plasma source 202 and the processing chamber 212. By providing the recirculated processing gases after the remote plasma source 202, deposition along the inlet conduit 210 that may result due to the presence of the recirculated gas may be reduced. Additionally, the plasma generated in the remote plasma source 202 may clean away deposits that may form within the inlet conduit 210 due to the presence of the recirculated gases.

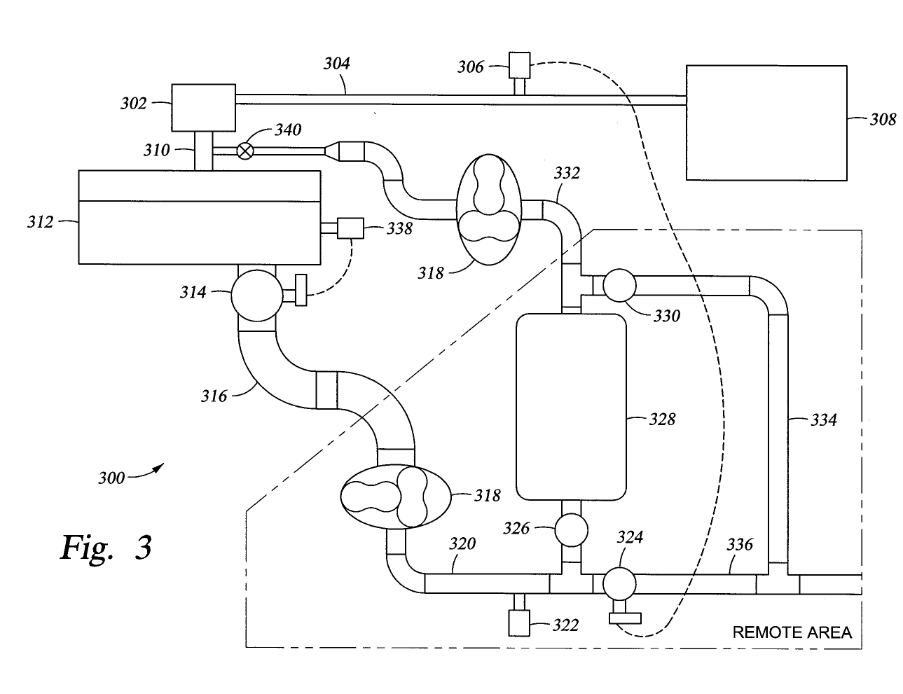

FIG. 3 is a drawing showing another embodiment of a dilution gas recirculation system 300. Process gas from a gas panel 308 may be provided to a processing chamber 312 through conduits 304, 310. A plasma of the processing gas may be struck in a remote plasma source 302 positioned between the gas panel 308 and the processing chamber 312. The processing chamber 312 may be evacuated by mechanical backing pumps (not shown). One or more pressure boosting devices 318, positioned between the processing chamber 312 and the mechanical backing pumps may assist in evacuating the processing chamber 312. In one embodiment, the pressure boosting device 318 may be a roots blower. In another embodiment, the pressure boosting device 318 may be a mechanical pump. Additionally, a pressure boosting device 318 may be positioned along the conduit 332 back to the processing chamber 312. The processing gas may be evacuated to the mechanical backing pumps through conduits 316, 320, and 336 from the processing chamber 312. An exhaust pressure gauge 322 may measure the pressure in the conduit 320.

A chamber pressure gauge 338 may measure the pressure within the processing chamber 312. A chamber throttle valve 314 may be opened and closed to control the amount of processing gas evacuated from the processing chamber 312. The amount that the chamber throttle valve 314 is opened is a function of the pressure as measured at the chamber pressure gauge 338. The chamber pressure gauge 338 and the chamber throttle valve 314 may be coupled together. In one embodiment, the pressure measured at the chamber pressure gauge 338 may be about 0.3 Torr to about 25 Torr. In another embodiment, the pressure measured at the chamber pressure gauge 338 may be about 0.3 Torr to about 15 Torr.

A portion of the processing gases evacuated from the processing chamber 312 may be recirculated back to the processing chamber 312 through a particle trap/filter 328. A recirculation throttle valve 324 may control the amount of processing gases that are evacuated to the mechanical backing pumps and how much processing gas is recirculated to the particle trap/filter 328. The mechanical backing pumps pull the processing gas through the particle trap/filter 328 when the shut off valve 330 is opened. A portion of the processing gases pulled through the particle trap/filter 328 may be evacuated to the mechanical backing pumps through a conduit 334 while a portion may be recirculated back to the processing chamber 312 through a conduit 332. A recirculation/isolation valve 326 and a shut-off valve 340 may additionally be provided that may be opened or closed to allow or prevent gas from being recirculated back to the processing chamber 312.

The recirculation throttle valve 326 may be coupled with the inlet pressure gauge 306 positioned along an inlet conduit 304. The inlet pressure gauge measures the pressure of the fresh, unrecirculated processing gas provided to the processing chamber 312. Based upon the measured pressure at the inlet pressure gauge 306, the amount that the recirculation throttle valve 326 may be opened may be controlled. In one embodiment, the pressure measured at the inlet pressure gauge may be about 1 Torr to about 100 Torr. In another embodiment, the pressure measured at the inlet pressure gauge 306 may be about 1 Torr to about 20 Torr.

The recirculation throttle valve 324 and the inlet pressure gauge 306 may be coupled together to control the mass flow rate of processing gas to the processing chamber 312. In one embodiment, a desired mass flow rate of processing gas to the chamber 312 may be predetermined. Based upon the predetermined mass flow rate, the mass flow rate of the fresh, unrecirculated processing gas may be set to a constant or desired flow rate. The amount of recirculated processing gas may then be controlled as a function of the pressure of the fresh, unrecirculated processing gas as measured at the inlet pressure gauge 306 so that the combined input of fresh, unrecirculated processing gas and recirculated process gas provided to the processing chamber 312 equals the predetermined, desired mass flow rate of total processing gas to the chamber 312.

### Operation

The PECVD system described above may be used to deposit films on substrates such as solar panel substrates. Such films may include silicon containing films such as p-doped silicon layers (P-type), n-doped silicon layers (N-type), or intrinsic silicon layers (I-type) deposited to form a P-I-N based structure. The silicon containing films may be amorphous silicon, microcrystalline silicon, or polysilicon. Operation of a recirculation system will be discussed with reference to FIG. 2, but it should be understood that the recirculation system shown in FIG. 3 is equally applicable.

At startup, the recirculation system is not yet running and the recirculation throttle valve 228 is fully open to allow all processing gases to be exhausted to the mechanical backing pumps 232. Fresh processing gas may be delivered from the gas source 208 to the remote plasma source 202 through the conduit 204. The fresh processing gas may include deposition gases, inert gases, and diluting gases such as hydrogen gas. The gases may be provided to separate conduits 204 to the remote plasma source 202 or through a single conduit 204. In one embodiment, the deposition gases may be plumbed directly to the processing chamber 212 which the diluting gas and the inert gas may be provided directly to the remote plasma source 202.

The inlet pressure gauge 206 measures and controls the amount of fresh processing gas that is provided to the remote plasma source 202. After a plasma is struck in the remote plasma source 202, the processing gas continues to the processing chamber 212 where deposition may occur. The processing gas, once used, is evacuated from the processing chamber 212 through a conduit 216 by mechanical backing pumps 232. A chamber pressure gauge 234 measures the pressure within the processing chamber 212. In order to maintain the proper pressure within the processing chamber 212, a chamber throttle valve 214 may be opened or closed based upon the pressure measured at the chamber pressure gauge 234. One or more pressure boosting devices 218 may be positioned between the processing chamber 212 and the backing pumps 232.

The used processing gas may then flow through a particle trap/filter 224 where particulates may be removed from the gas. The recirculation throttle valve 228 may be fully opened to permit all of the processing gas evacuated from the processing chamber 212 to be evacuated from the system upon process initiation. However, as the process proceeds and the desired chamber pressure is achieved and maintained, the processing gas may begin to be recirculated. The recirculation throttle valve 228 may close partially or entirely. The amount that the recirculation throttle valve 228 is opened or closed is a function of the pressure as measured at the inlet pressure gauge 206.

As the recirculation throttle valve 228 is closed, the amount of fresh, unrecirculated processing gas that is provided to the remote plasma source 202 is correspondingly reduced to ensure that the desired amount of processing gas is added to the processing chamber 212. As amount of fresh, unrecirculated processing gas as measured at the inlet pressure gauge 206 is reduced, the recirculation throttle valve 228 may be closed to ensure that sufficient processing gas is recirculated back to the processing chamber 212 to maintain the desired processing chamber pressure. In one embodiment, the recirculation throttle valve 208 may be closed so that all of the processing gas is recirculated.

The processing gas mixture that is provided to the processing chamber 212 may include silane-based gases and hydrogen gas. Suitable examples of silane-based gases include, but are not limited to, mono-silane (SiH₄), di-silane (Si₂H₆), silicon tetrafluoride (SiF₄), silicon tetrachloride (SiCl₄), and dichlorosilane (SiH₂Cl₂), and the like. The gas ratio of the silane-based gas and H₂ gas may be maintained to control the reaction behavior of the gas mixture, thereby allowing a desired proportion of crystallization. For an intrinsic microcrystalline film, the amount of crystallization may be between about 20 percent and about 80 percent. In one embodiment, the ratio of silane-based gas to H₂ may be between about 1:20 to about 1:200. In another embodiment, the ratio may be about 1:80 to about 1:120. In another embodiment, the ratio may be about 1:100. Inert gas may also be provided to the processing chamber 212. The inert gas may include Ar, He, Xe, and the like. The inert gas may be supplied at a flow ratio of inert gas to H₂ gas of between about 1:10 to about 2:1.

Prior to depositing the intrinsic microcrystalline silicon layer, a thin seed layer of intrinsic microcrystalline silicon may be deposited using the silane-based gases and H₂ as discussed above. The gas mixture may have a ratio of silane-based gas to H₂ of about 1:100 to about 1:20000. In one embodiment, the ratio may be about 1:200 to about 1:1000. In another embodiment, the ratio may be about 1:500.

It is to be understood that while the invention has been described above with a single conduit containing the processing gas from the gas panel, multiple conduits, each containing one or more processing gases may be used with each conduit having its own inlet pressure gauge that are collectively coupled with the recirculation throttle valve. In one embodiment, the dilution gas may be provided in its own, separate conduit directly to the remote plasma source. In another embodiment, the deposition gas may be provided from the gas panel to the chamber through its own, separate conduit without passing through the remote plasma source. In yet another embodiment, the recirculated processing gas may be plumbed directly to the processing chamber rather than joining with the fresh, unrecirculated processing gases at a location between the remote plasma source and the processing chamber.

By recirculating process gases, the amount of fresh, unrecirculated processing gases may be reduced. By using less fresh, unrecirculated processing gas, the cost of depositing a layer onto a substrate by PECVD may be decreased because less money may be spent on fresh, unrecirculated processing gas. Thus, by recirculating exhausted process gas, a PECVD process may proceed in an efficient manner.

While the foregoing is directed to embodiments of the present invention, other and further embodiments of the invention may be devised without departing from the basic scope thereof, and the scope thereof is determined by the claims that follow.

1. A plasma enhanced chemical vapor deposition method, comprising:
providing a fresh, unrecirculated processing gas to a plasma enhanced chemical vapor deposition chamber, the processing gas comprising a diluting gas and a deposition gas;
performing a plasma enhanced chemical vapor deposition process;
exhausting the processing gas from the chamber; and
recirculating at least a portion of the processing gas through gas reconditioning hardware that includes at least one item selected from the group consisting of a particle trap, a particle filter, and combinations thereof.

2. The method of claim 1, further comprising:
cleaning the at least one item, wherein the cleaning comprises exposing the at least one item to etching gases or water.

3. The method of claim 1, wherein the recirculated processing gas joins with the fresh, unrecirculated processing gas at a location between the chamber and a remote plasma source.

4. The method of claim 1, wherein the recirculation functions as a nested loop.

5. The method of claim 4, wherein, initially, the method proceeds without any recirculation gas initially and then recirculation gas is provided.

6. The method of claim 1, wherein the chamber comprises an inlet pressure gauge and a recirculation throttle valve, the method further comprising:
maintaining a desired mass flow rate of the fresh, unrecirculated processing gas to the process chamber; and
controlling the amount of gas evacuated through the recirculation throttle valve, the amount of gas evacuated is a function of the pressure of the processing gas as measured at the inlet pressure gauge.

7. The method of claim 6, wherein the inlet pressure gauge and the recirculation throttle valve are controlled together.

8. The method of claim 6, wherein the chamber comprises a chamber pressure gauge and a chamber throttle valve, the method further comprising:
controlling the amount of gas evacuated through the chamber throttle valve to maintain a constant chamber pressure, the amount of gas evacuated is a function of the pressure as measured at the chamber pressure gauge.

9. The method of claim 1, wherein the diluting gas comprises a gas selected from the group consisting of hydrogen, nitrogen, Nobel gases, and combinations thereof.

10. The method of claim 9, wherein the gases include helium, argon, and combinations thereof.

11. The method of claim 1, wherein the chamber comprises a chamber pressure gauge and a chamber throttle valve, the method further comprising:
controlling the amount of gas evacuated through the chamber throttle valve to maintain a constant chamber pressure, the amount of gas evacuated is a function of the pressure as measured at the chamber pressure gauge.

12. The method of claim 1, wherein the deposition gas comprises a silicon containing compound.

13. A plasma enhanced chemical vapor deposition method, comprising:
providing a fresh, unrecirculated processing gas to a plasma enhanced chemical vapor deposition chamber, the processing gas comprising at least hydrogen and a silane;
performing a plasma enhanced chemical vapor deposition process;
exhausting the processing gas from the chamber; and
recirculating at least a portion of the processing gas through gas reconditioning hardware that includes at least one item selected from the group consisting of a particle trap, a particle filter, and combinations thereof.

14. The method of claim 13, further comprising:
cleaning the particle trap, particle filter, or combinations thereof, wherein the cleaning comprises exposing the particle trap, particle filter, or combinations thereof to etching gases or water.

15. The method of claim 13, wherein the recirculated processing gas joins with the fresh, unrecirculated processing gas at a location between the chamber and a remote plasma source.

16. The method of claim 13, wherein the chamber comprises an inlet pressure gauge and a recirculation throttle valve, the method further comprising:
maintaining a desired mass flow rate of fresh, unrecirculated processing gas to the remote plasma source; and
controlling the amount of gas evacuated through the recirculation throttle valve, the amount of gas evacuated is a function of the pressure of the processing gas as measured at the inlet pressure gauge.

17. The method of claim 16, wherein the pressure measured at the inlet pressure gauge is controlled to be about 1 to about 100 Torr.

18. The method of claim 17, wherein the chamber comprises a chamber pressure gauge and a chamber throttle valve, the method further comprising:
controlling the amount of gas evacuated through the chamber throttle valve to maintain a desired chamber pressure, the amount of gas evacuated is a function of the pressure as measured at the chamber pressure gauge.

19. The method of claim 18, wherein the pressure measured at the chamber pressure gauge is controlled to be about 0.3 to about 25 Torr.

20. The method of claim 13, wherein the chamber comprises a chamber pressure gauge and a chamber throttle valve, the method further comprising:
controlling the amount of gas evacuated through the chamber throttle valve to maintain a desired chamber pressure, the amount of gas evacuated is a function of the pressure as measured at the chamber pressure gauge.

21. The method of claim 20, wherein the pressure measured at the chamber pressure gauge is controlled to be about 0.3 to about 25 Torr.

22. The method of claim 13, wherein at least one silicon containing layer is deposited, wherein the silicon containing layer is selected from the group consisting of a P-doped layer, an N-doped layer, an intrinsic silicon layer, and combinations thereof.

23. The method of claim 22, wherein the at least one silicon containing layer is selected from the group consisting of an amorphous layer, a polycrystalline layer, and a polysilicon layer.

24. A plasma enhanced chemical vapor deposition apparatus, comprising:
a chamber;
a processing gas source coupled with the chamber;
a first pressure gauge coupled between the processing gas source and the chamber; and
a chamber exhaust system coupled with the chamber, the exhaust system comprising:
at least one exhaust conduit coupled with the chamber;
a particle filter coupled along the at least one exhaust conduit;
a particle filter exhaust conduit coupled with the particle filter and the chamber; and
at least one throttle valve coupled with the particle filter exhaust conduit and electrically coupled with the first pressure gauge.

25. The apparatus of claim 24, further comprising:
a pressure boosting device coupled between the particle filter and the chamber.

26. The apparatus of claim 25, wherein the particle filter comprises a material compatible with etching gases.

27. The apparatus of claim 24, further comprising:
a remote plasma source coupled between the processing gas source and the chamber.

28. The apparatus of claim 27, wherein the particle filter exhaust conduit is coupled with the chamber at a location between the chamber and the remote plasma source.

29. The apparatus of claim 24, further comprising:
a chamber pressure gauge coupled with the chamber; and
a chamber throttle valve coupled at a location between the particle filter and the process chamber and electrically coupled with the chamber pressure gauge.

30. The apparatus of claim 24, further comprising:
an exhaust pressure gauge coupled along the exhaust conduit at a location between the chamber and the particle filter.

31. A plasma enhanced chemical vapor deposition apparatus, comprising:
a chamber;
a processing gas source coupled with the chamber;
a first pressure gauge coupled between the processing gas source and the chamber; and
a chamber exhaust system coupled with the chamber, the exhaust system comprising:
at least one exhaust conduit coupled with the chamber;
at least one throttle valve electrically coupled with the first pressure gauge along the at least one exhaust conduit;
a particle filter coupled between the chamber and the at least one throttle valve along the at least one exhaust conduit; and
a particle filter exhaust conduit coupled with the particle filter and the chamber.

32. The apparatus of claim 31, further comprising:
a pressure boosting device coupled between the particle filter and the chamber.

33. The apparatus of claim 32, wherein the particle filter comprises a material compatible with etching gases.

34. The apparatus of claim 31, further comprising:
a remote plasma source coupled between the chamber and the processing gas source.

35. The apparatus of claim 34, wherein the particle filter exhaust conduit is coupled with the chamber at a location between the chamber and the remote plasma source.

36. The apparatus of claim 31, further comprising:
a chamber pressure gauge coupled with the chamber; and
a chamber throttle valve coupled at a location between the particle filter and the process chamber and electrically coupled with the chamber pressure gauge.

37. The apparatus of claim 31, further comprising:
an exhaust pressure gauge coupled along the exhaust conduit at a location between the chamber and the particle filter.

38. The apparatus of claim 37, further comprising:
at least one mechanical backing pump coupled with the particle filter exhaust conduit.

39. The apparatus of claim 38, wherein the at least one mechanical pump is additionally coupled with the exhaust conduit at a location before the particle filter.

40. The apparatus of claim 31, further comprising a recirculation valve coupled between the particle filter and the process chamber.

41. A plasma enhanced chemical vapor deposition apparatus, comprising:
a chamber;
a processing gas source coupled with the chamber; and
a recirculation system capable of recirculating an amount of process gas exhausted from the chamber back to the chamber, the amount of recirculated processing gas a function of fresh processing gas provided from the processing gas source to the chamber to ensure a desired amount of processing gas is provided to the chamber, the system comprising:
one or more pressure boosting devices;
one or more mechanical pumps; and
a valve coupled between the one or more pressure boosting devices and the one or more mechanical pumps, wherein the valve controls the amount of the exhausted gas recirculated to the chamber and the amount of exhausted gas removed from the apparatus.
